(19) United States
(12) Patent Application Publication
(10) Pub. No.: US 2013/0113038 A1
(43) Pub. Date: May 9, 2013

(54) TRENCH MOSFET WITH SPLIT TRENCHED GATE STRUCTURES IN CELL CORNERS FOR GATE CHARGE REDUCTION

(71) Applicant: Fu-Yuan HSIEH, New Taipei City (TW)

(72) Inventor: Fu-Yuan HSIEH, New Taipei City (TW)

(73) Assignee: FEEI CHERNG ENTERPRISE CO., LTD., New Taipei City (TW)

(21) Appl. No.: 13/291,534

(22) Filed: Nov. 8, 2011

(51) Int. Cl. H01L 29/78

(52) U.S. Cl. 257/330; 257/E29.262

(57) ABSTRACT

A trench MOSFET with closed cells having split trenched gates structure in trenched gates intersection area in cell corner is disclosed. The invented split trenched gates structure comprises an insulation layer between said split trenched gates with thick thermal oxide layer in center portion of the trenched gates intersection area, therefore further reducing Qgd of the trench MOSFET without increasing additional Rds.

### FIELD OF THE INVENTION

This invention relates generally to the device configuration and manufacturing methods for fabricating the semiconductor power devices. More particularly, this invention relates to an improved and novel device configuration and manufacturing process for providing trench Metal-Oxide-Semiconductor-Field-Effect-Transistor (MOSFET) with split trenched gate structures in cell corners for gate charge reduction.

### BACKGROUND OF THE INVENTION

Conventional trench Metal-Oxide-Semiconductor-Field-Effect-Transistor (MOSFET) comprises either closed cell array or stripe cell array. Compared to that having stripe cell array, trench MOSFET having closed cell array has lower Rds (resistance between drain and source, similarly hereinafter) resulted from a greater channel length. However, it also has disadvantage of higher Qgd (gate charge between gate and drain, similarly hereinafter) contributed from inherent existence of intersection area among the closed cells.

Please refer to FIG. 1 for top view of a conventional N-channel trench MOSFET having closed cells with truncated corners of prior art. The Qgd aforementioned of the N-channel trench MOSFET is composed of Qgd1 and Qgd2, wherein Qgd1 is the gate charge between gate and drain in the intersection area (as illustrated in FIG. 1) among the truncated corners of the closed cells, as shown in FIG. 2A of C1-D1 cross section of FIG. 1, and Qgd2 is the gate charge between gate and drain in non-intersection area of trenched gates, as shown in FIG. 2B of A1-B1 cross section of FIG. 1. When unit cell (as illustrated in FIG. 1) has 1.0 um pitch, the portion of Qgd1 contributes about 40% of total Qgd due to a large area in the trenched gates intersection area.

For more detailed, please refer to FIG. 2B for A1-B1 cross-sectional view of FIG. 1, where a trenched source-body contact 102 having top view of rectangular shape is formed with vertical sidewall and located in center portion between every two trenched gates 108 which induce Qgd2 in each unit cell. A plurality of n+ source regions 104 encompassed in P body regions 106 are formed having uniform doping profile distributed from the vertical sidewall of the trenched source-body contact 102 to channel region near the trenched gates 108 filled with doped poly-silicon layer.

Accordingly, it would be desirable to provide a new and improved trench MOSFET configuration and manufacturing method to reduce Qgd in closed cell structure without increasing Rds.

### SUMMARY OF THE INVENTION

It is therefore an aspect of the present invention to provide a new and improved trench MOSFET by forming split trenched gates in cell corners in each trenched gates intersection area. Meanwhile, an insulation layer is formed between the split trenched gates with thick bottom thermal oxide layer underneath in center portion of the trenched gates intersection area. Therefore, Qgd1 is reduced because the center portion of the trenched gates intersection area is the composite oxide layer not poly-silicon layer.

Another aspect of the present invention is to form a doped area with dopant type opposite to epitaxial layer to further reduce Qgd1 by surrounding the split trenched gates underneath each the trenched gates intersection area.

Briefly, in a preferred embodiment, this invention disclosed a trench MOSFET comprising a plurality of closed cells with a substantial square shape for each cell, formed in an epitaxial layer of a first conductivity type onto a substrate of the first conductivity type, further comprising a plurality of trenched gates, wherein each trenched gates intersection area in cell corners comprising: split trenched gates along trench sidewalls of the trenched gates, wherein the trench sidewalls are padded with a gate oxide layer; an insulation layer covering top surface of the trenched gates and the epitaxial layer, and disposed between the split trenched gates; one thermally grown oxide layer formed between the insulation layer and the split trenched gates; another thermally grown oxide layer formed underneath the insulation layer in center portion of each the trenched gates intersection area, having thicker oxide than the gate oxide layer.

In an exemplary embodiment, the trench MOSFET further comprises: a plurality of source regions of the first conductivity type encompassed in body regions of second conductivity type in upper portion of the epitaxial layer and extending between every two adjacent of the trenched gates; a trenched source-body contact in each the closed cell and penetrating through the insulation layer covering the epitaxial layer, and further extending between through the source region and into the body region to connect the source region and the body region to a source metal covering top surface of the insulation layer; an ohmic body doped region of the second conductivity type encompassed in the body region and wrapping at least bottom of each the trenched source-body contact underneath the source region, wherein the ohmic body doped region has a higher doping concentration than the body region. In an exemplary embodiment, the trench MOSFET further comprises a on-resistance reduction doped region of the first conductivity type surrounding bottom of each the trenched gate and the trenched gates intersection area, wherein the on-resistance reduction doped area has a higher doping concentration than the epitaxial layer. In an exemplary embodiment, the trench MOSFET further comprises a gate-drain charge reduction doped region of the second conductivity type surrounding bottom of each the trenched gates intersection area. In an exemplary embodiment, the trench MOSFET further comprises a void existing between the split trenched gates in each the trenched gates intersection area. In an exemplary embodiment, the source region has a Gaussian distribution profile from sidewalk of the trenched source-body contact to adjacent channel regions near the trenched gates. In an exemplary embodiment, the trenched source-body contact has slope sidewalls and the ohmic body doped region surrounds bottom and sidewall of the trenched source-body contact underneath the source region. In an exemplary embodiment, the trenched gates have rounded trenched gates corners and the trenched source-body contact has circular shape form top view.

Furthermore, this invention discloses to method to manufacture a trench MOSFET comprising the steps of: opening a plurality of gate trenches in an epitaxial layer of a first conductivity type; carrying out ion implantation of the first conductivity type dopant above the gate trenches to form a on-resistance reduction doped region in the epitaxial layer and surrounding bottom of each the gate trenches as well as each trenched gates intersection area, wherein the doping concentration of the on-resistance reduction doped region is higher than that of the epitaxial layer; forming a gate oxide layer covering top surface of the epitaxial layer, and along inner surface of the gate trenches and the trenched gates intersection area; depositing a doped poly-silicon layer onto the gate oxide layer and etching the doped poly-silicon layer to a pre-determined depth; carrying out a body ion implantation of second conductivity type dopant to form body regions in upper portion of the epitaxial layer; applying a poly mask and performing dry poly-silicon etching to form a poly-silicon hole in center portion of the doped poly-silicon layer in the trenched gates intersection area, wherein the poly hole extends from top surface of the doped poly-silicon layer in the trenched gates intersection area to expose the gate oxide on bottom of the trenched gates intersection area; carrying out an ion implantation of the second conductivity type dopant to form a gate-drain charge reduction doped region of the second conductivity type below the poly-silicon hole; Carrying out a body diffusion to form the body regions of the second conductivity type as well as gate-drain charge reduction doped region underneath the trenched gates intersection area; depositing an insulation layer onto entire top surface and filling into the poly hole; providing a contact mask and carrying out a dry oxide etching to open contact openings through the insulation layer; carrying out ion implantation of the first conductivity type and diffusion step to form source regions in upper portion of the body regions with a Gaussian distribution profile form edge of the contact openings to adjacent channel regions near the gate trenches; carrying out a dry silicon etching to make the contact openings further extending through the source regions and into the body regions to form contact trenches; carrying out ion implantation of the second conductivity type and followed by a step of RTA to form an ohmic body doped region in the body regions and surrounding at least bottom of each the contact trench underneath the source regions, wherein the ohmic body doped region has higher doping concentration than the body region; depositing a barrier layer overlying inner surface of the contact trenches and top surface of the insulation layer; depositing a metal material onto a barrier metal layer and etching back the metal material leaving it within the contact trenches; etching back the barrier layer removing it from top surface of the insulation layer; depositing a front metal layer onto top surface of the insulation layer and covering the metal material to function as a source metal.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a top view of a trench MOSFET with closed cells of prior art.

FIG. 2A is C1-D1 cross section of the trench MOSFET in FIG. 1.

FIG. 2B is A1-B1 cross section of the trench MOSFET in FIG. 1.

FIG. 3 is a top view of a trench MOSFET according to the present invention.

FIG. 4A is a preferred A2-B2 cross section of the trench MOSFET in FIG. 3 according to the present invention.

FIG. 4B is a preferred C2-D2 cross section of the trench MOSFET in FIG. 3 according to the present invention.

FIG. 5A is another preferred A2-B2 cross section of the trench MOSFET in FIG. 3 according to the present invention.

FIG. 5B is another preferred C2-D2 cross section of the trench MOSFET in FIG. 3 according to the present invention.

FIG. 6 is another preferred C2-D2 cross section of the trench MOSFET in FIG. 3 according to the present invention.

FIG. 7 is another preferred C2-D2 cross section of the trench MOSFET in FIG. 3 according to the present invention.

FIG. 8 is another top view of a trench MOSFET according to the present invention.

FIG. 9A˜9I are a serial of cross-sectional views for showing the processing steps for fabricating the trench MOSFET with A2-B2 cross section as FIG. 5A and C2-D2 cross section as FIG. 7

FIG. 10 is a cross-sectional view for showing an alternative step during fabrication process in FIG. 9F.

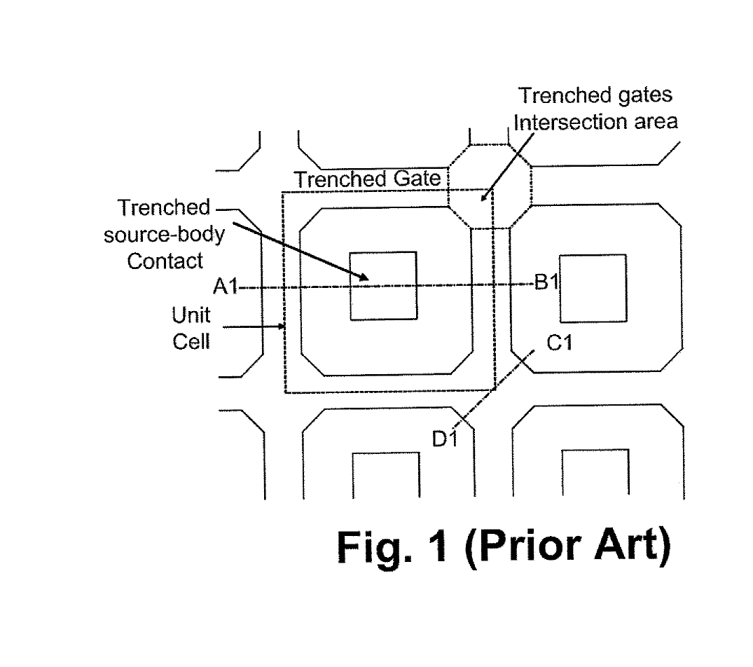

### DETAILED DESCRIPTION OF THE EMBODIMENTS

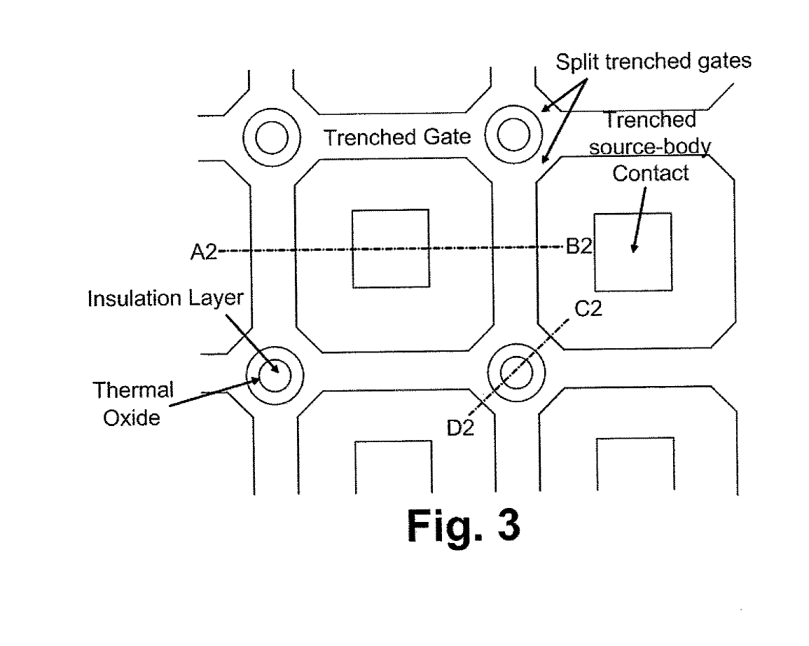

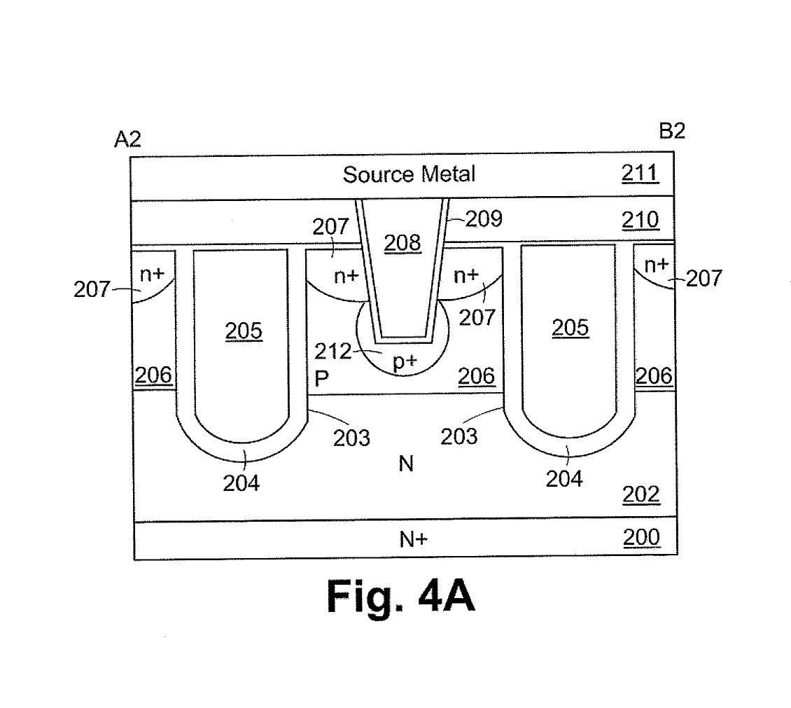

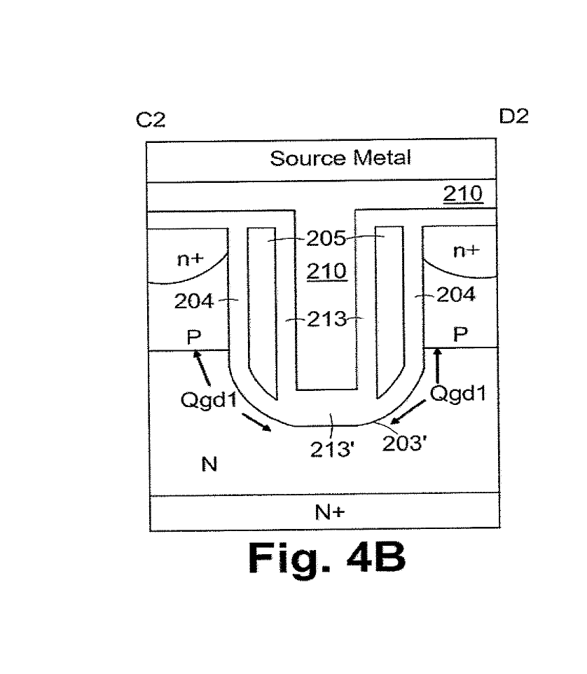

Please refer to FIG. 4A and FIG. 4B for a preferred A2-B2 cross section and C2-D2 cross section of the trench MOSFET in FIG. 3 which shows a plurality of substantial square closed cells with split trenched gates. In FIG. 4A, an N-channel trench MOSFET is formed on an N+ substrate 200 supporting an N epitaxial layer 202. A plurality of gate trenches 203 are formed within the N epitaxial layer 202 and padded with a gate oxide layer 204 along inner surface. Onto the gate oxide layer 204, A doped poly-silicon layer 205 is deposited filling within the gate trenches 203 to form a plurality of trenched gates for the N-channel trench MOSFET. A plurality of P body regions 206 in upper portion of the N epitaxial layer 202 surround the trenched gates and encompass n+ source regions 207 near top surface of the N epitaxial layer 202. A tungsten plug 208 padded with a barrier metal layer of Ti/TiN or Co/TiN is formed filling a contact trench 209 with slope sidewalls to function as a trenched source-body contact which penetrates through an insulation layer 210, the n+ source region 207 and extending into the P body region 206 to connect the n+ source region 207 and the P body region 206 and connects to a source metal 211 of Al alloys overlying a layer of Ti or Ti/TiN. According to the present invention, each the n+ source region 207 has a Gaussian distribution doping profile from sidewalls of the contact trench 209 to adjacent channel regions near the trenched gates. Within the P body region 206, a p+ ohmic body doped region 212 is formed surrounding bottom and sidewalls of each the contact trench 209 underneath the n+ source region 207.

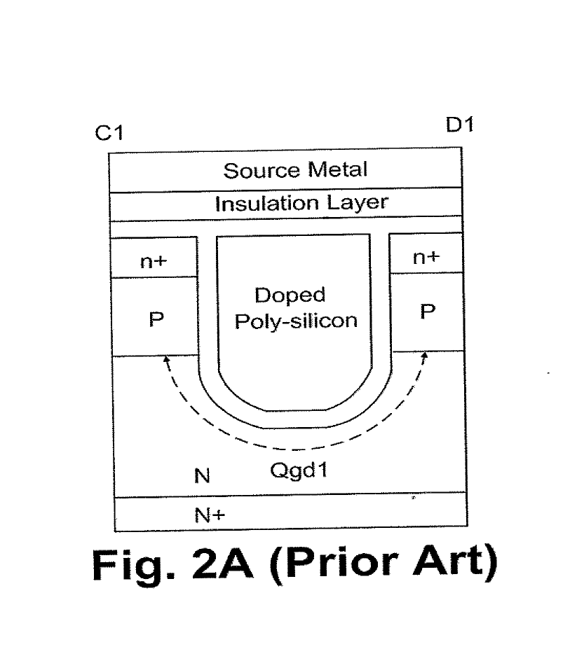

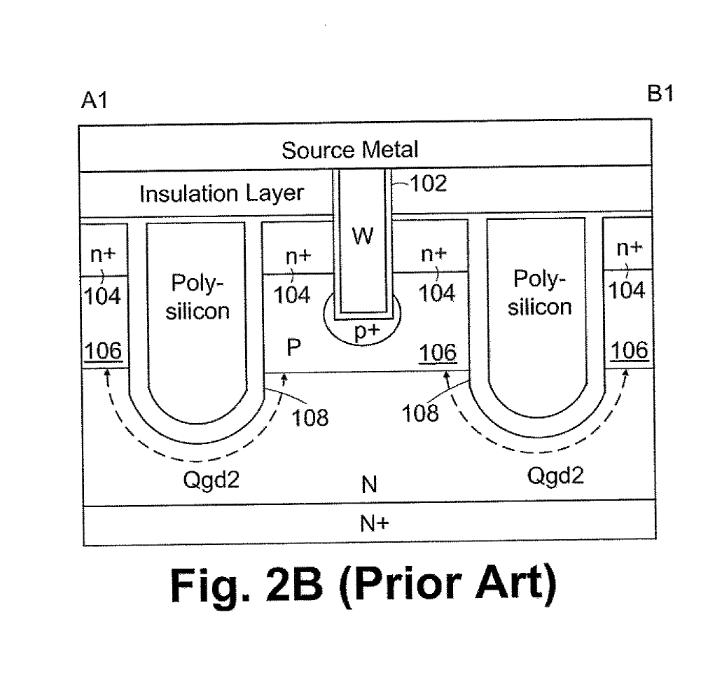

FIG. 4B shows the trenched gates intersection area in cell corner which comprises a gate trench 203′ padded by the gate oxide layer 204 along inner surface. The trenched gates intersection area further comprises split trenched gates of the doped poly-silicon 205 formed along sidewalls of the gate trench 203′. The insulation layer 210 described above also extends between the split trenched gates with a thermal oxide layer 213′ underneath in center portion of the trenched gates intersection area. Meanwhile, between the split trenched gates 205 and the insulation layer 210, there is another thermal oxide layer 213 along sidewall of the split trenched gates, wherein the thermal oxide layer 213′ is thicker than the gate oxide 204 because the thermal oxide layer 213′ also comprises the gate oxide layer 204 along trench bottom. Because the center portion of the trenched gates intersection area comprises the thermal oxide layer 213′ not doped poly-silicon, Qgd1 of the N-channel trench MOSFET is obviously reduced compared to FIG. 2A, as illustrated in FIG. 4B.

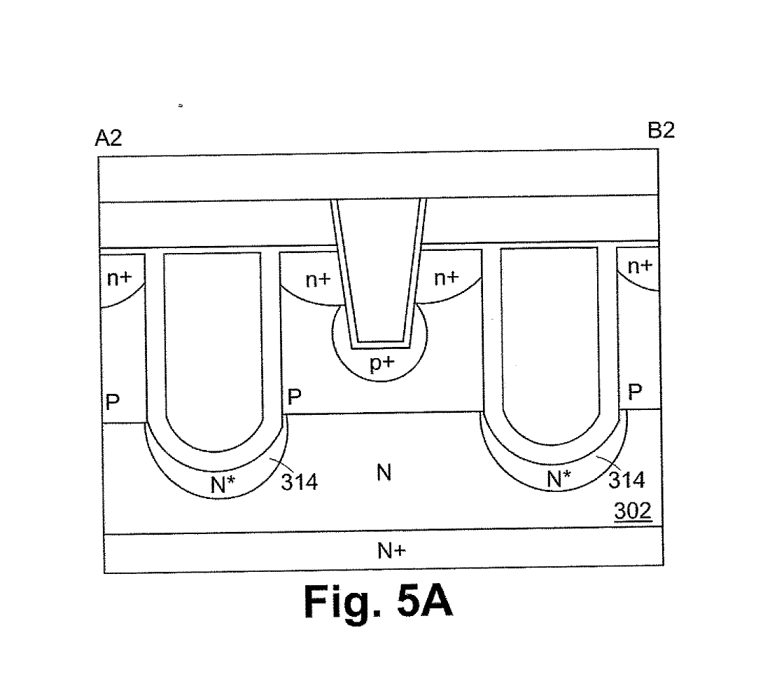

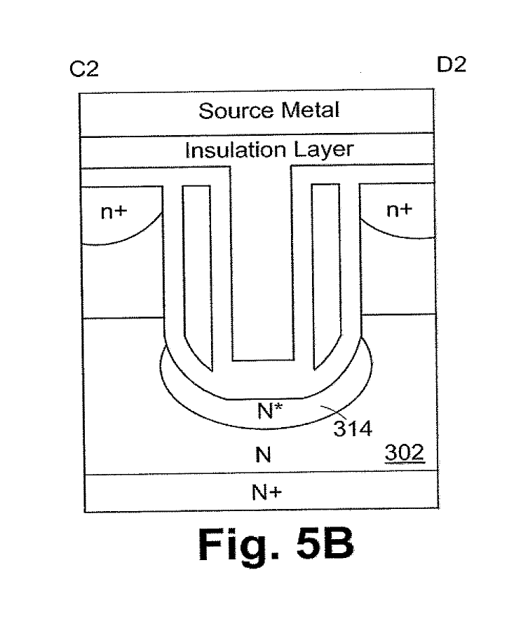

Please refer to FIG. 5A and FIG. 5B for another preferred A2-B2 cross section and C2-D2 cross section of the trench MOSFET in FIG. 3. In FIG. 5A, the N-channel trench MOSFET has a similar structure to FIG. 4A except that, there is an N* on-resistance reduction doped region 314 formed within the N epitaxial layer 302 and surrounding bottom of each the trenched gate to further reduce Qgd of the N-channel trench MOSFET wherein the N* on-resistance reduction doped region 314 has a higher doping concentration than the N epitaxial layer 302. In FIG. 5B, there is also an additional N* on-resistance reduction doped region 314 formed within the N epitaxial layer 302 and surrounding bottom of the trenched gates intersection area compared to FIG. 4B.

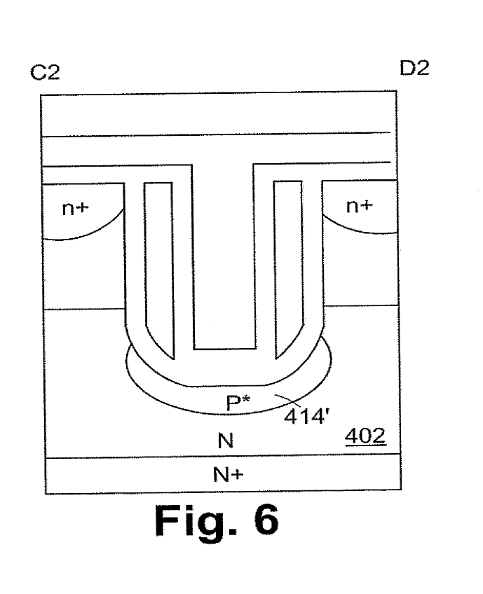

Please refer to FIG. 6 for another preferred C2-D2 cross section of the trench MOSFET in FIG. 3. Compared to FIG. 5B, the trenched gates intersection area in FIG. 6 has an additional P* gate-drain charge reduction doped area 414′ formed within the N epitaxial layer 402 and surrounding bottom of the trenched gates intersection area to further reduce Qgd1.

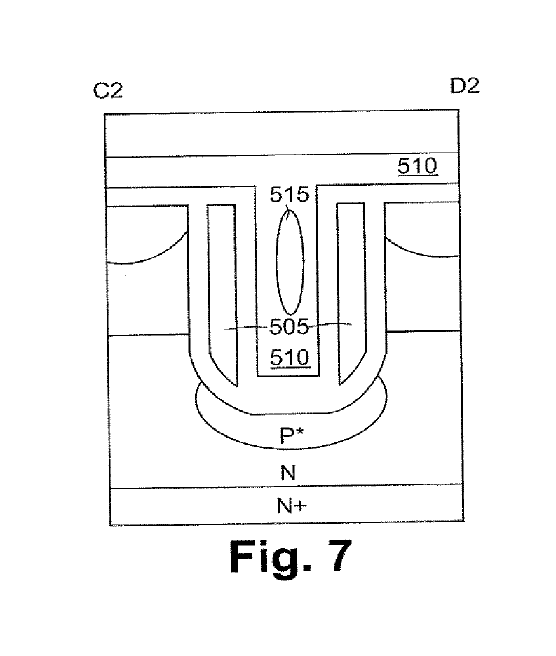

Please refer to FIG. 7 for another preferred C2-D2 cross section of the trench MOSFET in FIG. 3. Compared to FIG. 6, the insulation layer 510 in FIG. 7 has a void 515 existing between the split trenched gates of doped poly-silicon layer 505 due to the insulation layer 510 not able to fill up the narrow area between the split trenched gates during fabrication process.

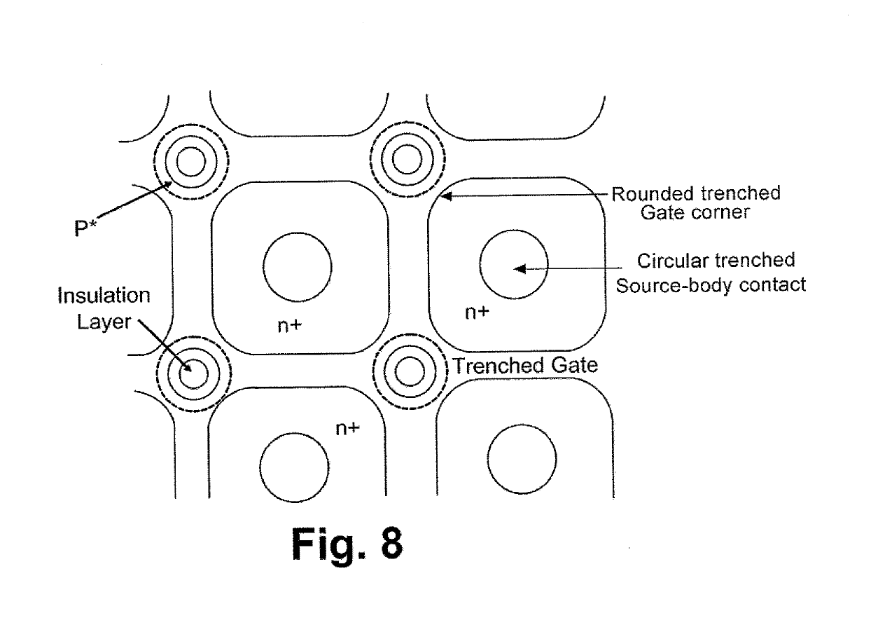

Please refer to FIG. 8 for another top view of the trench MOSFET according to this invention. Compared to FIG. 3, except for the implementation of the P* gate-drain charge reduction doped region, the trench MOSFET in FIG. 8 has rounded trenched gate corners and circular trenched source-body contact to further save die area.

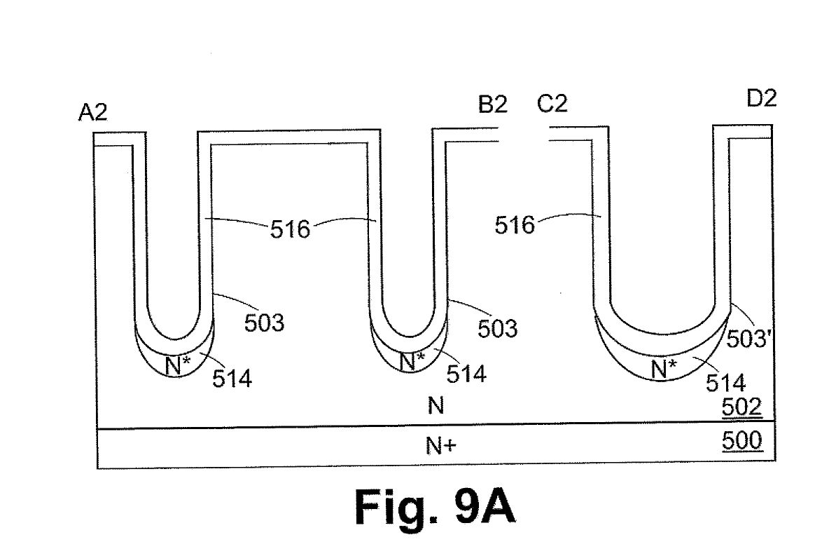

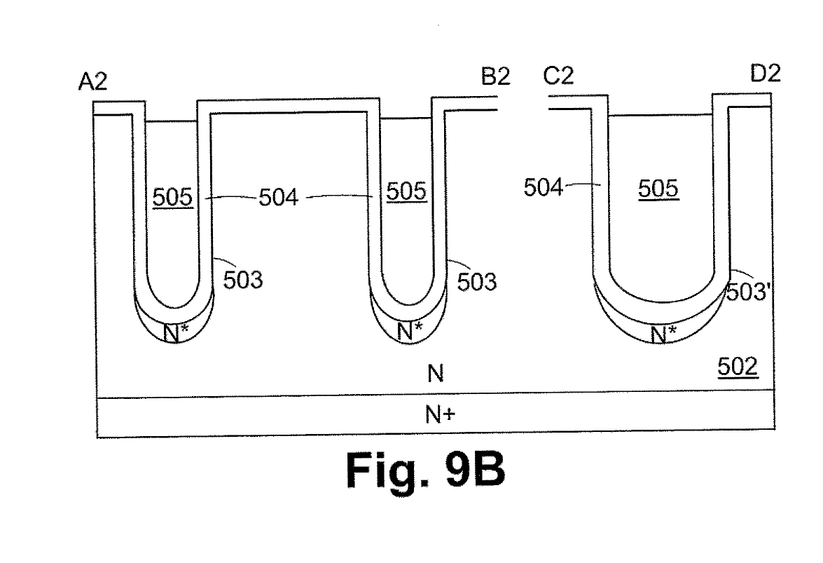

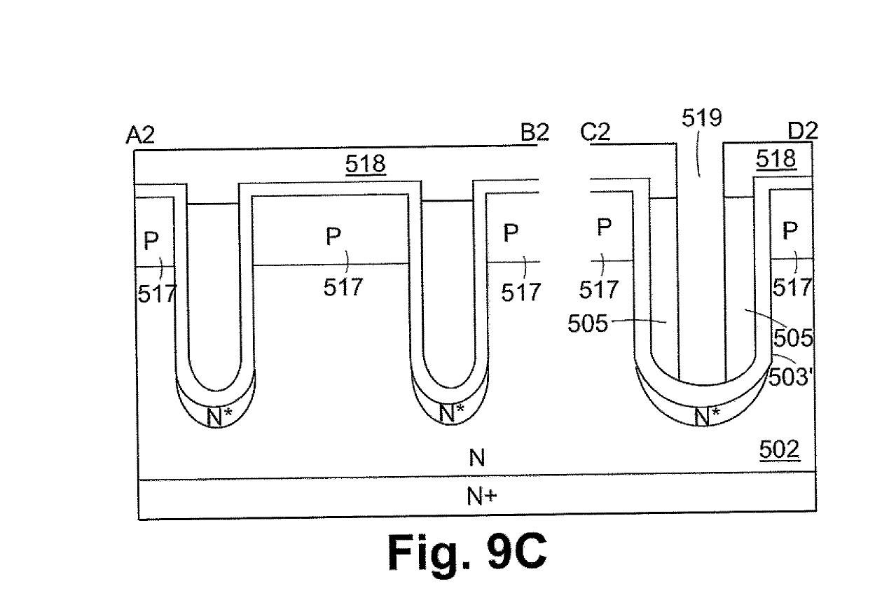

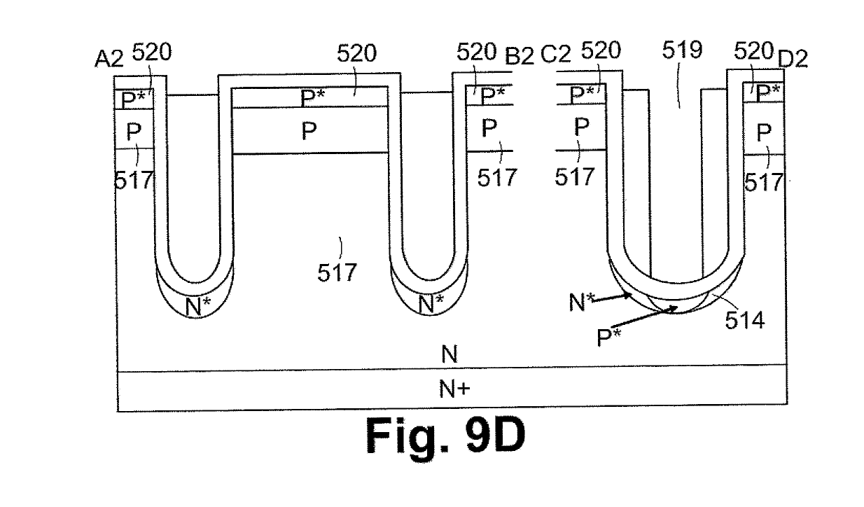

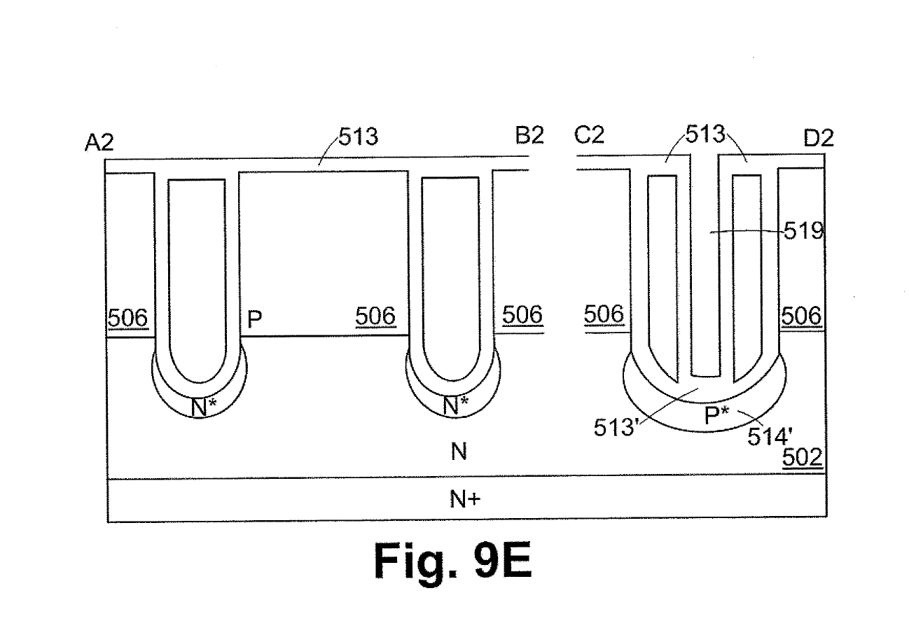

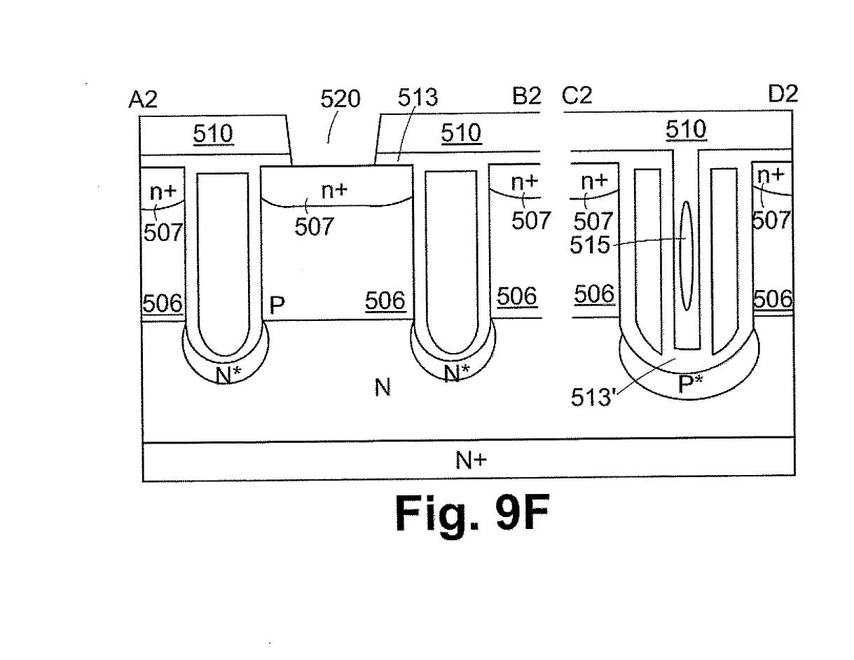

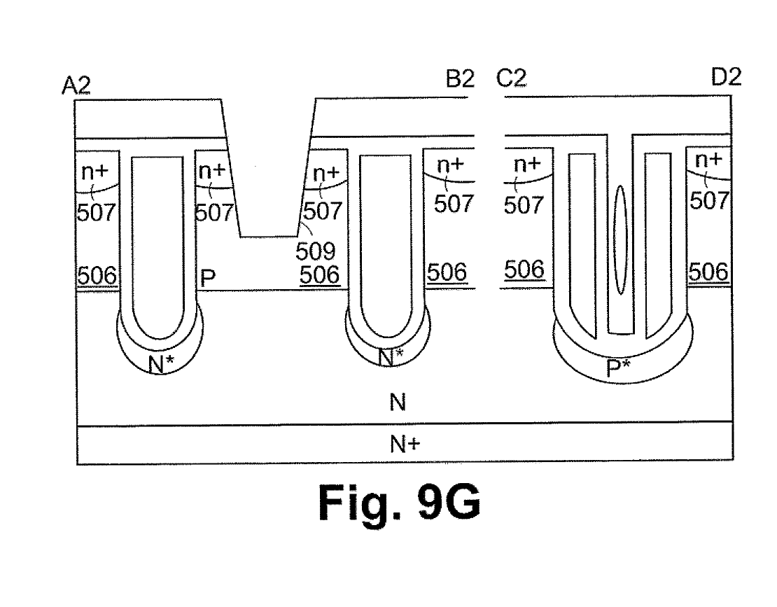

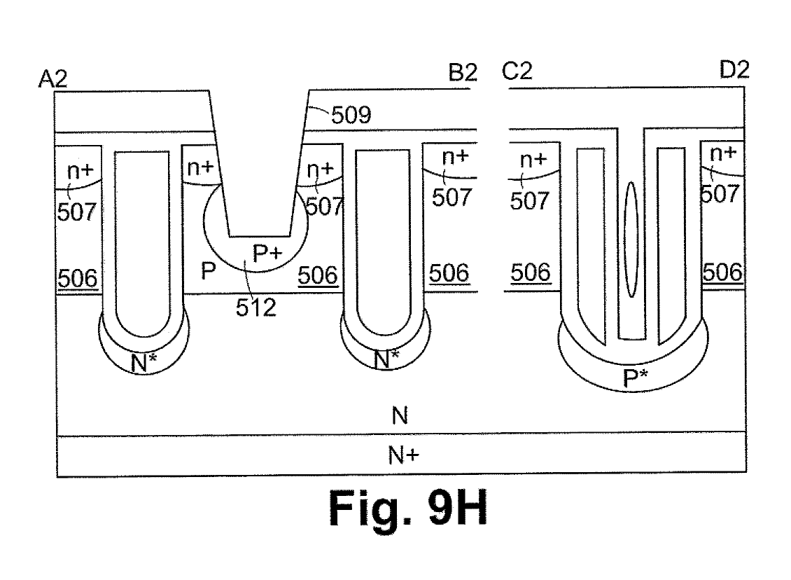

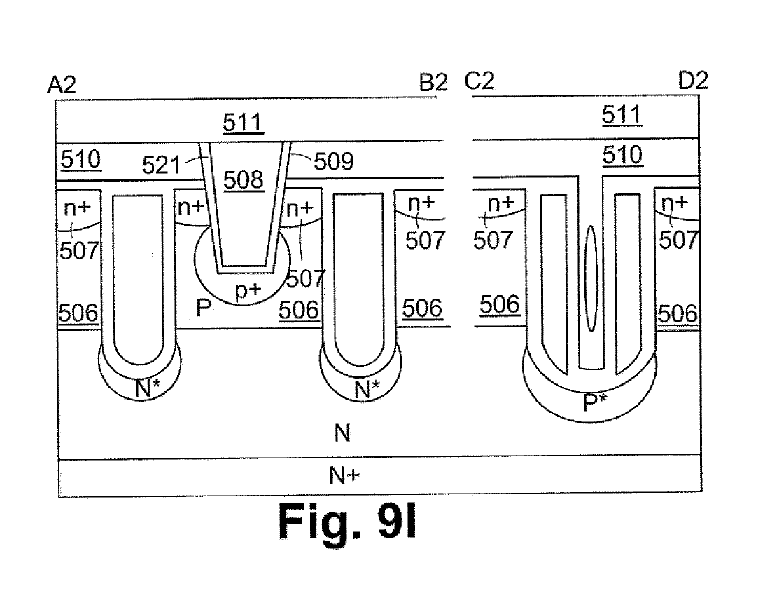

Referring to FIGS. 9A to 9I for a series of cross-sectional views to illustrate the processing steps for manufacturing a trench MOSFET with C2-D2 cross sectional as FIG. 7 and A2-B2 cross section as FIG. 5A. In FIG. 9A, a trench mask (not shown) is applied to open a plurality of gate trenches 503 by dry silicon etching process in an N epitaxial layer 502 supported on an N+ substrate 500, wherein the gate trench located in gate trenches intersection area is illustrated as 503′, as shown in C2-D2 cross section. Then, a sacrificial oxide layer (not shown) is grown and removed to repair the sidewall surface of the gate trenches 503 and 503′ damaged by the trench etching process. Next, a screen oxide 516 is grown for preventing ion implantation damage. Then an Arsenic ion implantation is carried out to form N* on-resistance reduction region 514 surrounding bottom of each gate trench 503 and 503′ with higher doping concentration than the N epitaxial layer 502.

In FIG. 9B, the screen oxide 516 is first removed and a gate oxide layer 504 is deposited or grown overlying inner surface of the gate trenches 503 and 503′ and also onto top surface of the N epitaxial layer 502. After that, the gate trenches 503 and 503′ are filled with a doped poly-silicon layer 505 followed by dry etching or CMP (Chemical Mechanical Polishing) of the doped poly-silicon layer 505 to remove it from above the top of the gate trenches and further to a pre-determined depth, forming a plurality of trenched gates for the trench MOSFET.

In FIG. 9C, a Boron ion implantation is carried out to form a P type implantation area 517 in upper portion of the N epitaxial layer 502. Next, after applying a poly mask 518, a dry poly etching is carried out to form a poly hole 519 defined by the poly mask 518 in center portion of the doped poly-silicon layer 505 in the gate trench 503′. The poly hole 519 is extending from top surface of the doped poly-silicon layer 505 in the gate trench 503′ to expose center bottom of the gate trench 503′, therefore implementing split trenched gates structure in trenched gates intersection area in cell corner as shown in C2-D2 cross section.

In FIG. 9D, after removing the poly mask 518, a P type dopant ion implantation is carried out to form a P* gate-drain charge reduction doped region 520 in upper portion of the P type implantation area 517, as well as in the trench bottom underneath the poly hole 519.

In FIG. 9E, a step of body diffusion is performed to form a plurality of P body regions 506 extending between the trenched gates, as well as a P* gate-drain charge reduction doped region 514′ underneath the trenched gates intersection area and surrounding bottom of the split trenched gates. Then, a step of thermal oxidation is carried out in the body diffusion to form a thermal oxide layer along sidewall of the split trenched gates and covering top surface of the plurality of trenched gates and the N epitaxial layer 502. Meanwhile, at bottom of the poly hole 519, the thermal oxidation also increases thickness of the gate oxide 504 on center portion of the trench bottom to form another thermal oxide layer 513′. Obviously, the thermal oxide layer 513′ is thicker than the gate oxide 504.

In FIG. 9F, an insulation layer 510 comprising BPSG (Boron Phosphorus Silicon Glass) and undoped TEOS (Tetraethyl Orthosilicate) is deposited covering the first thermal oxide layer 513 and extending between the split trenched gates to fill the poly hole and reach the second thermal oxide layer 513′. During the insulation layer deposition process, a void 515 is induced due to the insulation layer 510 not able to fill up the narrow poly hole area between the split trenched gates. Then, a contact mask (not shown) is applied onto the insulation layer 510 to define location of contact trench. Next, a dry oxide etching is performed to removing the insulation layer and the thermal oxide layer from where according to the contact mask to form a plurality of contact openings 520 with slope sidewalls. Then, an n+ source ion implantation and diffusion is carried out through the contact openings 520 to form n+ source regions 507 in upper portion of the P body regions 506 with a Gaussian distribution profile from edge of the contact openings 520 to channel regions near the trenched gates.

In FIG. 9G, the contact openings 520 are etched to further extending through the n+ source regions 507 and into the P body regions 506 with slope sidewalls by dry Silicon etching to form a plurality of contact trenches 509.

In FIG. 9H, a step of P type dopant BF2 ion implantation is carried out to form a p+ ohmic body doped region 512 within the P body region 506 and surrounding bottom and sidewalls of each the contact trench 509 underneath the n+ source regions 507. Then, a RTA (Rapid Thermal Annealing) is performed to activate the P type dopant in the p+ ohmic body doped region 512.

In FIG. 9I, a layer of Ti/TiN 521 is first deposited along inner surface of each the contact trench 509 and top surface of the insulation layer 510 to function as barrier metal layer, then, tungsten metal is deposited onto the barrier layer and filling into the contact trench 509. After that, the tungsten metal and the barrier metal layer is etched back to be left within the contact trench 509 to act as tungsten plug 508. Next, a layer of Al alloys overlying a Ti or Ti/TiN layer, or Ti/Ni/Ag is deposited onto the tungsten plug 508 and the insulation layer 510 to act as a source metal 511 which connected to the n+ source regions 507 and the P body regions 506 via the tungsten plug 508.

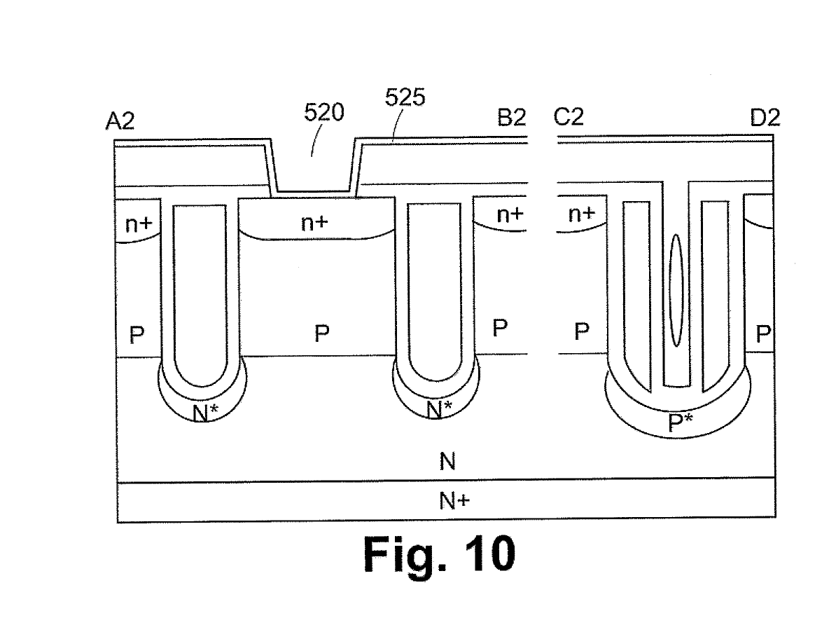

FIG. 10 is a cross-sectional view for showing an alternative step during fabricating the trench MOSFET which is similar with FIG. 9F except that, before the N type dopant ion implantation, a thin screen oxide layer 525 is deposited along inner surface of the contact opening 520 to minimize ion implantation damage. The screen oxide layer 525 is then removed before the dry Silicon etching as in FIG. 9G.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A trench MOSFET comprising a plurality of closed cells formed in an epitaxial layer of a fist conductivity type onto a substrate of said first conductivity type, further comprising a plurality of trenched gates filled in gate trenches, wherein each trenched gate intersection area in cell corners comprising:
split trenched gates along trench sidewalls of said trenched gates, wherein said trench sidewalls are padded with a first insulation layer as a gate oxide layer; and a second insulation layer disposed between said split trenched gates.

2. The trench MOSFET of claim 1 further comprising a third insulation layer thermally grown between said second insulation layer and each of said split trenched gates, and a fourth insulation layer thermally grown underneath said second insulation layer in a center portion of each intersection area of said trenched gates, wherein said fourth insulation layer is thicker than said first insulation layer.

3. The trench MOSFET of claim 1 further comprising;
a plurality of source regions of said first conductivity type encompassed in body regions of a second conductivity type in upper portion of said epitaxial layer and extending between every two adjacent of said trenched gates;
a trenched source-body contact in each said closed cell and penetrating through said source region and extending into said body region to connect said source region and said body region to a source metal covering top surface of said second insulation layer;
an ohmic body doped region of said second conductivity type encompassed in said body region and wrapping at least bottom of each said trenched source-body contact underneath said source region, wherein said ohmic body doped region has a higher doping concentration than said body region.

4. The trench MOSFET of claim 1 further comprising an on-resistance reduction doped region of said first conductivity type in said epitaxial layer and surrounding each bottom of said trenched gates, wherein said on-resistance reduction doped region has a higher doping concentration than said epitaxial layer.

5. The trench MOSFET of claim 1 further comprising a gate-drain charge reduction doped region of a second conductivity type in said epitaxial layer and surrounding bottom of each said trenched gate intersection area.

6. The trench MOSFET of claim 1 further comprising a void existing in said second insulation layer between said split trenched gates in each said trenched gate intersection area.

7. The trench MOSFET of claim 1, wherein said trenched gates and said split trenched gates are composed of a doped poly-silicon layer onto said gate oxide layer.

8. The trench MOSFET of claim 3, wherein said source region has Gaussian distribution profile from sidewalls of said trenched source-body contact to channel region near said trenched gates.

9. The trench MOSFET of claim 3, wherein said trenched source-body contact has slope sidewalls and said ohmic body doped region surrounds bottom and sidewalls of said trenched source-body contact underneath said source region.

10. The trench MOSFET of claim 3, wherein said trenched source-body contact is filled with a tungsten plug padded with a barrier metal layer of Ti/TiN or Co/TiN.

11. The trench MOSFET of claim 10, wherein said tungsten plug is connected to a front metal layer of Al alloys overlying a Ti or Ti/TiN layer.

12. The trench MOSFET of claim 1 wherein said closed cells constitutes substantially square shaped cells with rounded corner from top view.

13. The trench MOSFET of claim 3 wherein said trenched source-body contact has circular shape from top view.
